(19) United States
(12) Patent Application Publication
(10) Pub. No.: US 2012/0301630 A1
(43) Pub. Date: Nov. 29, 2012

(54) METHOD FOR FORMING FLEXIBLE PRINTED CIRCUIT BOARD

(76) Inventor: Chin-Chun Huang, Taoyuan (TW)

(21) Appl. No.: 13/241,144

(22) Filed: Sep. 22, 2011

(30) Foreign Application Priority Data
May 25, 2011 (TW) 100118325
May 25, 2011 (TW) 100209364

(51) Int. Cl. H05K 3/22; H05K 3/12

(52) U.S. Cl. 427/555; 427/96.9; 427/97.2; 427/97.8

(57) ABSTRACT

A method for forming a flexible printed circuit board is provided. First, an insulating substrate with a first side and a second side is provided. Second, a through hole connecting the first side and the second side is formed in the insulating substrate. Then, a printing step is carried out to print a conductive precursor which is on the first side and cover and fill the through hole. Later, the conductive precursor is cured to form a conductive composition and to simultaneously form a circuit to obtain a flexible printed circuit board. The conductive composition includes at least one of carbon and silver.

### BACKGROUND OF THE INVENTION

1. Field of the Invention

The present invention generally relates to a method for forming a flexible printed circuit board. In particular, the present invention is directed to a method of printing a conductive precursor which includes silver or carbon on an insulating substrate and further curing the conductive precursor for forming a flexible printed circuit board. The conductive precursor covers the first side and the second side of the flexible printed circuit board and fills the through hole which connects the first side and the second. The present invention is able to reduce the consumption of copper and to reduce the production cost as well.

2. Description of the Prior Art

The circuit board made of a flexible material has versatile uses in all of the current electronic products. Because copper has excellent electric conductivity, it is the premium choice for the conductive material of the circuits in the circuit boards.

Generally speaking, the method to fabricate the circuits in the circuit boards is usually to first provide a bulk of an insulating substrate which is covered with copper. Then, a patterned mask is formed on the copper layer to define the pattern of the circuits. Later, an etching procedure is used to remove excess copper to obtain the copper circuits disposed on the insulating substrate.

Recently, due to the increasing price of the raw materials, the cost for the insulating substrate covered with copper is drastically rising, too. In addition, after the etching procedure, most of the copper not serving as the circuits is removed. This not only causes a lot of waste but also generates a lot of waste copper solution to be disposed of, which does not keep up with the current environment-friendly trends.

In view of this, a new method for forming a flexible printed circuit board is still needed. The copper material is not needed, thereby saving the production cost for the expensive copper. Also, the procedure of etching copper is omitted as well to reduce the loss of the raw materials as much as possible to keep up with the current environment-friendly trends.

### SUMMARY OF THE INVENTION

Given the above, the present invention proposes a method for forming a flexible printed circuit board. Because the flexible printed circuit board does not use a bulk of copper sheet as the source of the conductive material, the production cost for the expensive copper is saved. Apart from this, the procedure of etching copper is omitted so the loss of the raw materials is reduced as much as possible to keep up with the environment-friendly trends.

In the method for forming a flexible printed circuit board of the present invention, first an insulating substrate with a first side and a second side is provided. Second, a through hole disposed in the insulating substrate and connecting the first side and the second side is formed. Then, a printing step is carried out to print a conductive precursor to be disposed on the first side and cover and fill the through hole. Next, the conductive precursor is cured to form a conductive composition and to simultaneously form a circuit to obtain a flexible printed circuit board. The conductive composition includes at least one of carbon and silver.

In one embodiment of the present invention, the conductive composition is substantially free of Cu.

In another embodiment of the present invention, the line width of the conductive composition is larger than 60 mm.

In another embodiment of the present invention, the pitch of the conductive composition is larger than 60 mm.

In another embodiment of the present invention, the conductive composition includes a cured carbon paste.

In another embodiment of the present invention, the line width of the conductive composition is about 100 mm-150 mm.

In another embodiment of the present invention, the pitch of the conductive composition is larger than 150 mm.

In another embodiment of the present invention, the diameter of the through hole is larger than 0.1 mm.

In another embodiment of the present invention, before the printing step the method further includes carrying out a surface modifying step to roughen the first side by plasma.

In another embodiment of the present invention, curing the conductive precursor is carried out between 130° C.-180° C. to cure the conductive precursor for 30 minutes-60 minutes.

In another embodiment of the present invention, a pre-treatment step may be carried out to treat the insulating substrate by plasma.

In another embodiment of the present invention, a surface cleaning step is carried out to clean the first side by static electricity.

In another embodiment of the present invention, the conductive composition forms an electrode of a certain symbol, such as a pattern, a character or a number.

In another embodiment of the present invention, the method further includes forming the conductive composition on the second side, and curing the conductive composition to form the conductive composition on the second side and cover the through hole so that the conductive composition on the second side and the conductive composition on the first side are electrically connected by the through hole.

In another embodiment of the present invention, the conductive composition includes a first conductive composition and a second conductive composition so that the first conductive composition covers the second conductive composition.

In another embodiment of the present invention, an electrically connecting pad is formed on the second side.

In another embodiment of the present invention, a circuit test is carried out on the conductive composition.

In another embodiment of the present invention, the method further includes forming a solder mask layer so that the solder mask layer covers the conductive composition on the first side.

In another embodiment of the present invention, the method further includes forming a solder mask layer so that the solder mask layer covers the conductive composition on the second side.

In another embodiment of the present invention, the insulating substrate is cut into smaller pieces such as stripes.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a flow chart of the method of the present invention for forming a flexible printed circuit board.

FIGS. 2-11 illustrate the method of the present invention for forming a flexible printed circuit board, in which

FIG. 2 illustrates a pre-treatment step;

FIG. 3 illustrates at least one through hole is formed in the insulating substrate;

FIG. 4 illustrates a pre-treatment step;

FIG. 5 illustrates a conductive precursor is cured to form a conductive composition;

FIG. 6 illustrates an electrically connecting pad is formed;

FIG. 7 illustrates a circuit test is carried out;

FIG. 8 illustrates a first conductive composition covers a second conductive composition;

FIG. 9 illustrates the pattern of the solder mask layer covers the pattern of the conductive composition;

FIG. 10 illustrates the pattern of the solder mask layer is complementary with that of the conductive composition;

FIG. 11 illustrates the insulating substrate is cut into smaller pieces.

### DETAILED DESCRIPTION

The present invention provides a method for forming a flexible printed circuit board. The production cost for the expensive copper is saved because the flexible printed circuit board does not use a bulk copper sheet as the source of the conductive material. The loss of the raw materials is reduced as much as possible. The conductive material in the flexible printed circuit board of the present invention may be cured silver paste, carbon paste or the combination thereof.

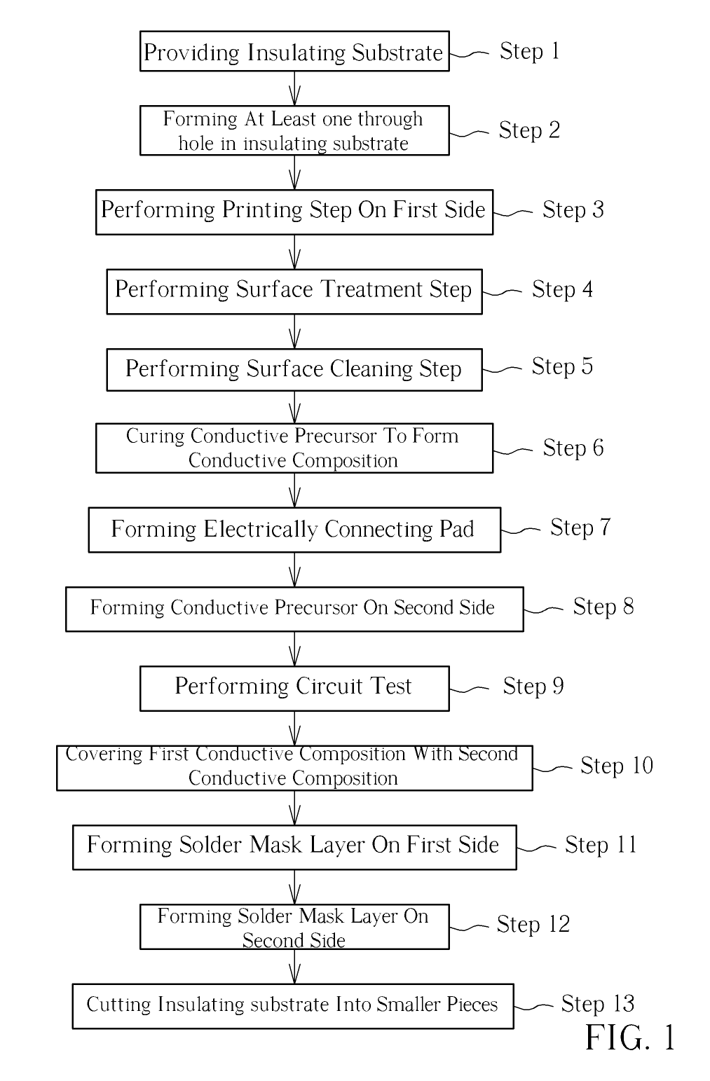

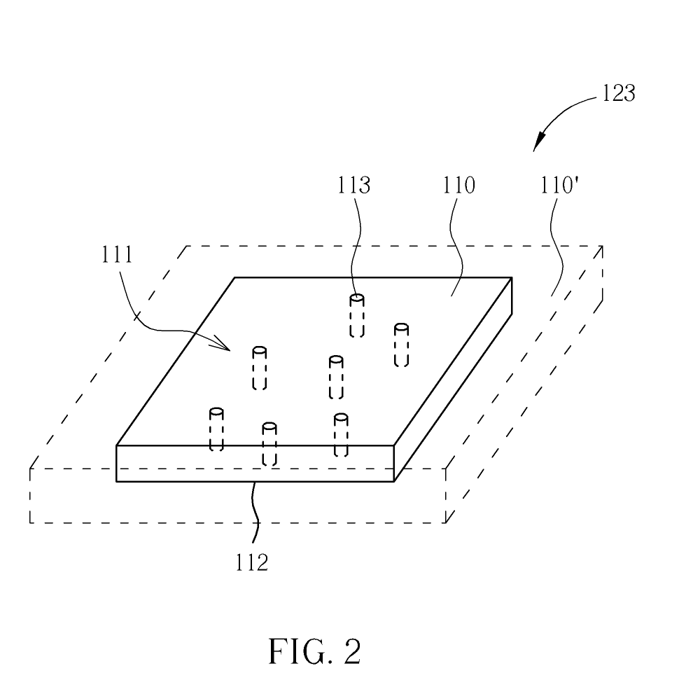

FIG. 1 illustrates a flow chart of the method for forming a flexible printed circuit board. FIGS. 2-11 illustrate the method for forming a flexible printed circuit board. First, please refer to FIGS. 1 and 2, an insulating substrate 110 is provided. The insulating substrate 110 has a first side 111 and a second side 112 which are opposite each other. The insulating substrate 110 is usually a flexible material which is able to withstand a temperature up to 150° C., such as polyethylene terephthalate (PET), polyimide or a glass fiber. Preferably, the insulating substrate 110 may undergo a pre-treating step for stabilizing the properties of the insulating substrate 110. For example, the insulating substrate 110 is baked in a temperature about 130° C.-180° C. for 30 minutes to 60 minutes to stabilize the size of the insulating substrate 110. The dotted line in FIG. 2 illustrates the insulating substrate 110′ before the pre-treatment.

Second, please refer to FIGS. 1 and 2, at least one through hole 113 is formed in the insulating substrate 110 for connecting the first side 111 and the second side 112. The through hole 113 may be formed by different ways so that the diameter of the through hole 113 is about 0.05 mm-0.5 mm and it is located where it is needed to be. For example, a drill is used to punch through the insulating substrate 110 so that the diameter of the through hole 113 is larger than 0.1 mm. Or alternatively, for a smaller hole, a laser may be used to form the through hole 113 so that the diameter of the through hole 113 may be as small as 0.05 mm.

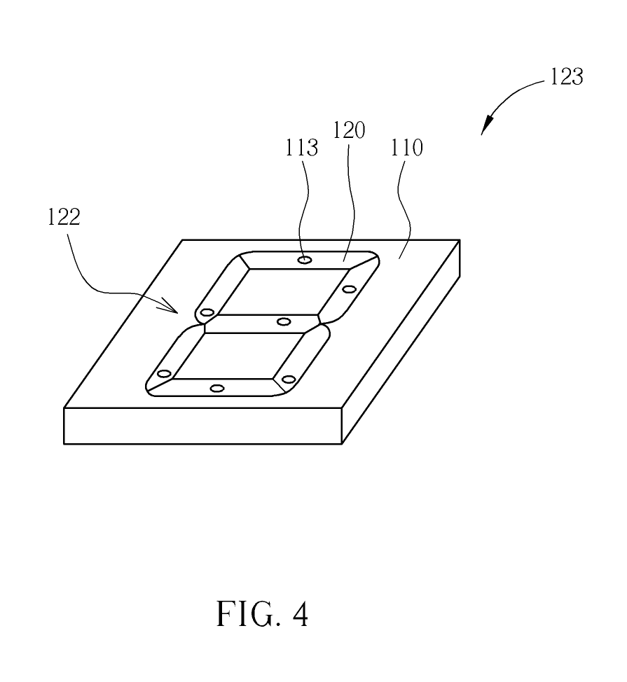

Then, please refer to FIGS. 1 and 4, a printing step is carried out on the first side 111 of the insulating substrate 110. For example, a screen printing step is used to print a conductive precursor 120 on the first side 111 of the insulating substrate 110 to obtain a pre-determined pattern. During the printing step, the conductive precursor 120 also covers and fills the through holes 113. The conductive precursor 120 forms at least one of a pattern, a character or a number.

The conductive precursor 120 is usually a paste-like composition and includes a conductive ingredient. For example, the conductive precursor 120 is usually a silver paste or a carbon paste. However, the conductive precursor 120 is substantially free of Cu. For example, Goo Chemical Co. Ltd. provides a conductive carbon paste (PCF-1038) for use in the circuits of a flexible printed circuit board. This conductive carbon paste has fine carbon particles and a lower sheet electric resistance and suitable for the screen printing. Please see the information provided by Goo Chemical Co. Ltd. for the detailed descriptions of the conductive carbon paste. Apart from this, Five Star Technologies (USA) provides a conductive silver paste (ElectroSperse™ X-207HV) for use in the circuits of a flexible printed circuit board.

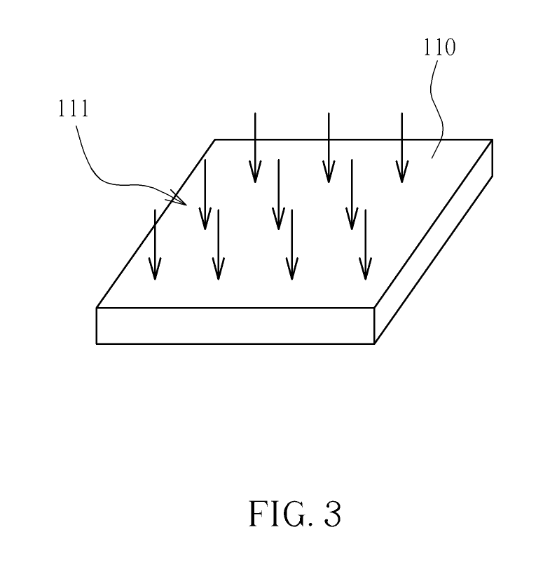

Optionally, please refer to FIGS. 1 and 3, before the printing step, a surface treatment step may be carried out, for example a surface modifying step to roughen the first side 111 and to enhance the affinity between the conductive precursor 120 and the insulating substrate 110. For example, the surface treatment step is carried out by plasma. Besides, please refer to FIGS. 1 and 3, optionally, a surface cleaning step may be carried out before the printing step to clean the first side 111. For example, the dust may be removed from the first side 111 by static electricity.

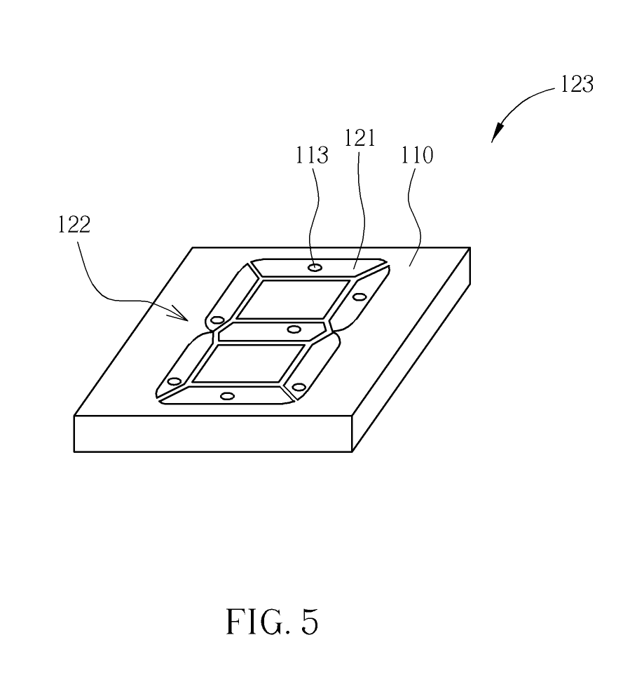

Next, please refer to FIGS. 1 and 5, a curing step is carried out to cure the conductive precursor 120 to form a conductive composition 121. For example, the conductive precursor 120 is cured in a temperature about 130° C.-180° C. for 30 minutes to 60 minutes. Because the conductive precursor 120 has a pre-determined pattern, the cured conductive composition 121 forms a pattern as well. The conductive composition 121 and the insulating substrate 110 together form a flexible printed circuit board 123. Because the conductive precursor 120 has a pre-determined pattern, the conductive composition 121 forms a pattern, a character or a number. For example, if the flexible printed circuit board 123 is used to show consumer information, the conductive composition 121 forms a number such as 0, 1, 2, 3, 4, 5, 6, 7, 8, 9 . . . etc. or a letter/character such as G, K, M, Q, e, f, t, v, [symbol] , Ψ, β, δ . . . etc. or a pattern $, *, %, £, [symbol] , ¥, [symbol] . . . etc. Preferably, the conductive composition 121 forms an electrode for showing the above information in, for example LCD, LED, or OLED.

Different conductive precursors 120 have different curing conditions. For instance, the conductive carbon paste PCF-1038 is cured in a temperature about 150° C. for about 30 minutes to obtain the conductive composition 121. If the conductive precursor 120 includes a cured silver paste, in the pattern formed by the circuits 121 the line width of the conductive composition 121 is not less than 60 mm, for example larger than 60 mm, or the line pitch of the conductive composition 121 is not less than 70 mm, for example larger than 70 mm.

If the conductive precursor 120 includes a cured carbon paste, in the pattern formed by the circuits 121 the line width of the conductive composition 121 may be 100 mm-150 mm and the line pitch of the conductive composition 121 may be not less than 150 mm, for example larger than 150 mm. The conductive composition 121 may also include a first conductive composition 124 and a second conductive composition 125.

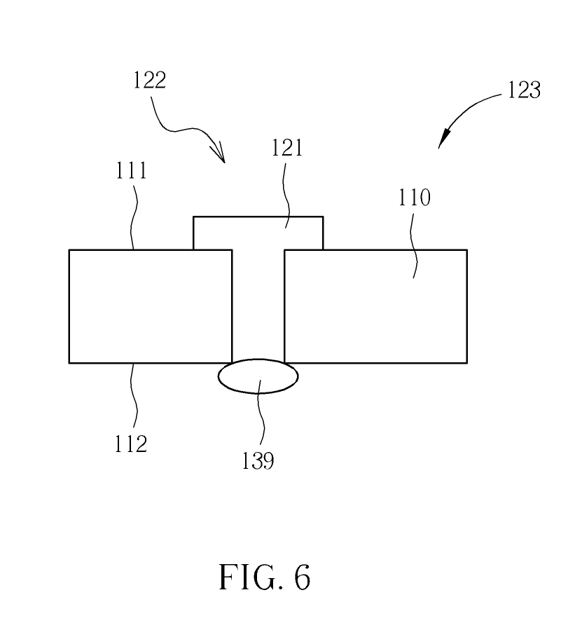

Optionally, please refer to FIGS. 1 and 6, an electrically connecting pad 139 may be formed on the second side 112. The electrically connecting pad 139 is not only disposed on the second side 112 but also covers the through hole 113. In such a way, the electrically connecting pad 139 serves as a medium for the outward electrical connection of the conductive composition 121 on the first side 111. After the above steps, a flexible printed circuit board 123 which has a single-sided conductive composition 121 serving as circuits 122 is obtained. The through hole 113 may extend the circuit 122 on the first side 111 to a pre-determined position on the second side 112.

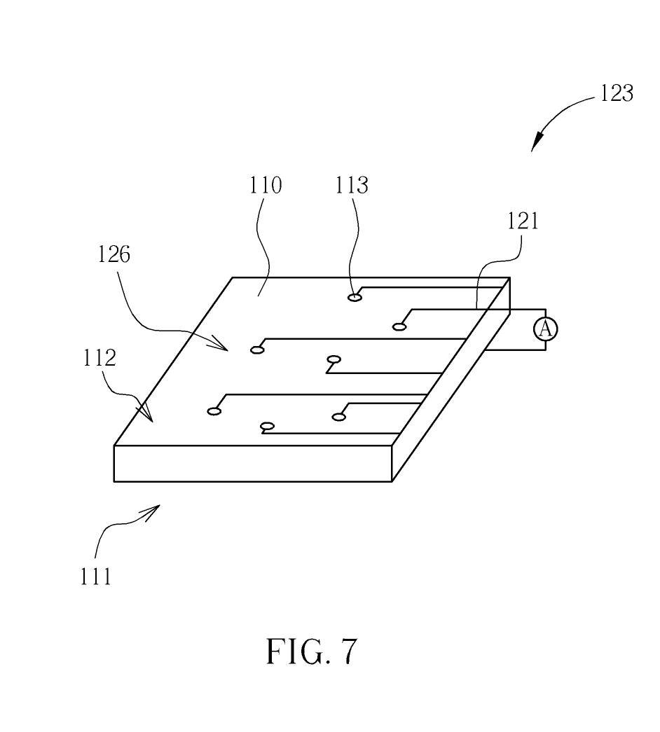

Optionally, in another embodiment of the present invention, the conductive precursor 120 may also be formed on the second side 112 so there is a conductive composition 121 which is electrically connected to the circuit 122 on the first side 111. Please refer to FIGS. 1 and 7 for the steps of forming the conductive composition. First, the conductive precursor 120 is formed on the second side 112. Then, as described earlier, the conductive precursor 120 is cured to form another conductive composition 121 on the second side 112. Another conductive composition 121 on the second side 112 also covers the other side of the through hole 113, so the conductive composition 121 on the second side 112 and the conductive composition 121 on the first side 111 are electrically connected by means of the through hole 113. The conductive composition 121 on the second side 112 may form a circuit layout 126 of a closed circuit or alternatively an open circuit, together with the conductive composition 121 on the first side 111.

Optionally, please refer to FIGS. 1 and 7, the conductive composition 121 on the first side 111 and/or on the second side 112 may undergo a circuit test to verify the reliability of the conductive composition 121. In this technical field, there are various circuit tests applicable to different flexible printed circuit boards 123. Since the circuit tests are known to persons in the art, the details will not be described here.

Although after the above steps a needed flexible printed circuit board 123 is obtained, the conductive composition 121 however is exposed to the ambient atmosphere. If the conductive composition 121 should have higher reliability, the fragile conductive composition 121 may be protected.

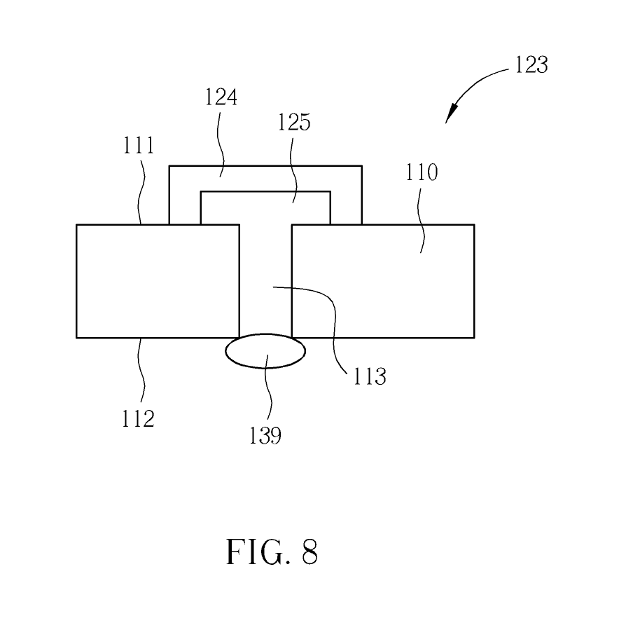

In one embodiment of the present invention, please refer to FIG. 8, a first conductive composition 124 may be used to cover a second conductive composition 125 so that the second conductive composition 125 is kept away from the possible contamination of outer moisture or dust. At this moment, the first conductive composition 124 may be a cured carbon paste.

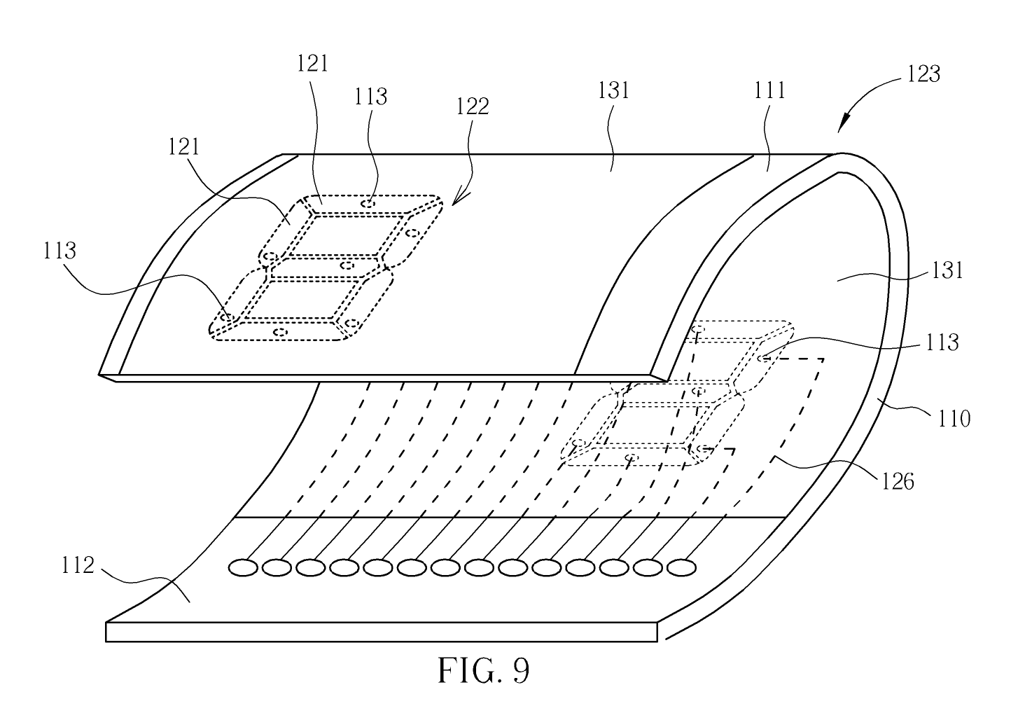

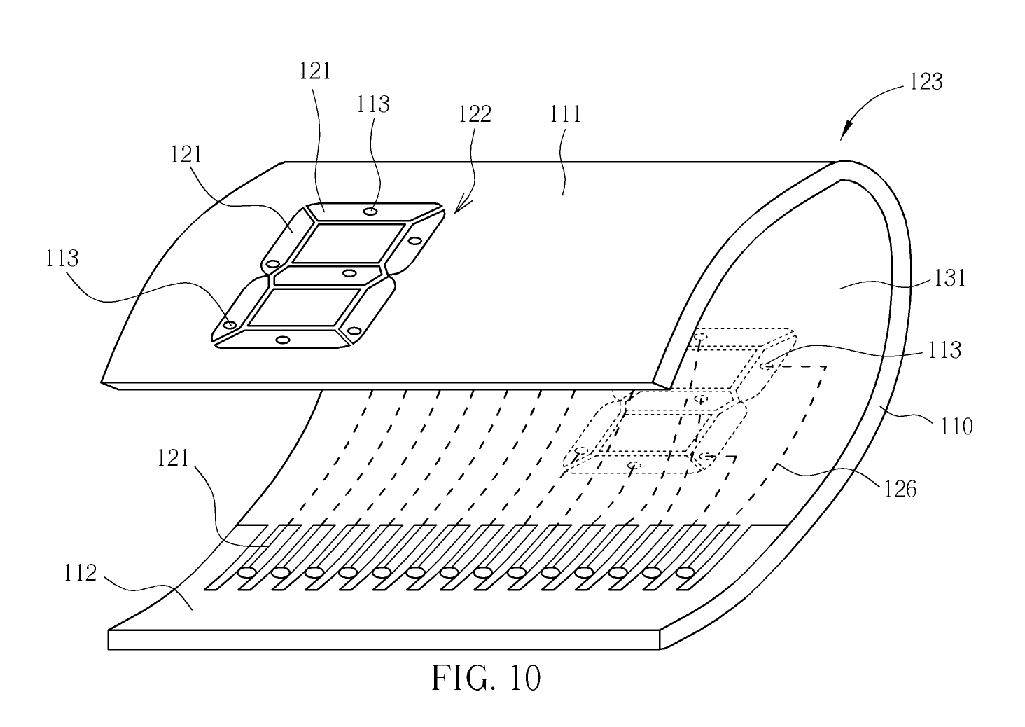

In another embodiment of the present invention, a solder mask layer 131 may be used to cover the insulating substrate 110 on the first side 111. Please refer to FIG. 9, the solder mask layer 131 is formed on the first side 111 so that the solder mask layer 131 covers the circuit 122. Or alternatively, please refer to FIG. 10, there is no solder mask layer 131.

In still another embodiment of the present invention, a solder mask layer 131 may be used to cover the insulating substrate 110 on the second side 112. Please refer to FIG. 9, the solder mask layer 131 is formed on the second side 112 so that the solder mask layer 131 covers the conductive composition 121. Or alternatively, please refer to FIG. 10, the pattern of the solder mask layer 131 is complementary with that of the conductive composition 121.

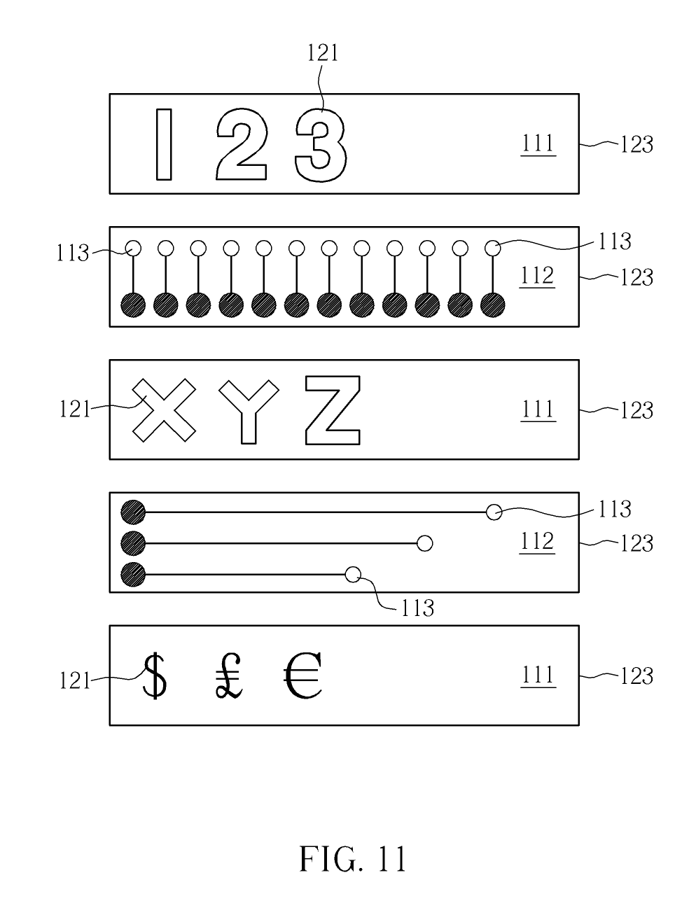

Optionally, the completed flexible printed circuit board 123 may be further cut to have a proper dimension. For example, as shown in FIG. 11, the insulating substrate 110 is cut into smaller pieces so that the flexible printed circuit board 123 is in a form of, for example, stripes.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for forming a flexible printed circuit board, comprising:
providing an insulating substrate with a first side and a second side;
forming a through hole disposed in said insulating substrate and connecting said first side and said second side;
performing a printing step to print a conductive precursor to be on said first side and cover and fill said through hole; and
curing said conductive precursor to form a conductive composition and to simultaneously form a circuit to obtain a flexible printed circuit board, wherein said conductive composition comprises at least one of carbon and silver.

2. The method for of forming a flexible printed circuit board claim 1, wherein said conductive composition is substantially free of Cu.

3. The method for of forming a flexible printed circuit board claim 1, wherein said insulating substrate comprises at least one of polyethylene terephthalate (PET), polyimide and a glass fiber.

4. The method for of forming a flexible printed circuit board claim 1, wherein the line width of said conductive composition is larger than 60 mm.

5. The method for of forming a flexible printed circuit board claim 1, wherein the pitch of said conductive composition is larger than 60 mm.

6. The method for of forming a flexible printed circuit board claim 1, wherein said conductive composition comprises a cured carbon paste.

7. The method for of forming a flexible printed circuit board claim 6, wherein the line width of said conductive composition is about 100 mm-150 mm.

8. The method for of forming a flexible printed circuit board claim 6, wherein the pitch of said conductive composition is larger than 150 mm.

9. The method for of forming a flexible printed circuit board claim 1, wherein said through hole is formed by at least one of a laser and a drill.

10. The method for of forming a flexible printed circuit board claim 1, wherein the diameter of said through hole is larger than 0.1 mm.

11. The method for of forming a flexible printed circuit board claim 1, further comprising:
forming an electrical connecting pad to be disposed on said second side and covering said through hole.

12. The method for of forming a flexible printed circuit board claim 1, before said printing step further comprising:
performing a surface modifying step to roughen said first side by plasma.

13. The method for of forming a flexible printed circuit board claim 1, further comprising:
performing a pre-treatment step to process said insulating substrate.

14. The method for of forming a flexible printed circuit board claim 1, wherein curing said conductive precursor is performed between 130° C.-180° C. to cure said conductive precursor for 30 minutes-60 minutes.

15. The method for of forming a flexible printed circuit board claim 1, wherein said conductive composition forms at least one of a pattern, a character or a number.

16. The method for of forming a flexible printed circuit board claim 1, wherein said conductive composition forms an electrode.

17. The method for of forming a flexible printed circuit board claim 1, further comprising:
forming said conductive composition on said second side; and
curing said conductive composition to form said conductive composition on said second side and cover said through hole so that said conductive composition on said second side and said conductive composition on said first side are electrically connected by said through hole.

18. The method for of forming a flexible printed circuit board claim 1, wherein said conductive composition on said second side forms a line.

19. The method for of forming a flexible printed circuit board claim 1, wherein said conductive composition on said second side and said conductive composition on said first side form an open circuit.

20. The method for of forming a flexible printed circuit board claim 1, wherein said conductive composition comprises a first conductive composition and a second conductive composition.

21. The method for of forming a flexible printed circuit board claim 20, wherein said first conductive composition covers said second conductive composition.

22. The method for of forming a flexible printed circuit board claim 20, wherein said first conductive composition comprises a carbon paste.

23. The method for of forming a flexible printed circuit board claim 1, further comprising:
forming a solder mask layer disposed on said first side so that said solder mask layer either covers said conductive composition or is complementary with said conductive composition.

24. The method for of forming a flexible printed circuit board claim 1, further comprising:
forming a solder mask layer disposed on said second side so that said solder mask layer either covers said conductive composition or is complementary with said conductive composition.
